(19) United States
(12) Patent Application Publication
(10) Pub. No.: US 2013/0226476 A1
(43) Pub. Date: Aug. 29, 2013

(54) Discrete time ESD test data logger

(71) Applicants: Sovann Samreth, San Bernadino, CA (US); Guillermo De La llsa, Corona, CA (US)

(72) Inventors: Sovann Samreth, San Bernadino, CA (US); Guillermo De La llsa, Corona, CA (US)

(73) Assignee: Botron Co. Inc.

(21) Appl. No.: 13/385,669

(22) Filed: Feb. 29, 2012

(51) Int. Cl. G06F 19/00; G01R 15/00

(52) U.S. Cl. 702/57

(57) ABSTRACT

The invention relates to a process and an apparatus for monitoring electrostatic threats or events, and for testing electrostatic dissipation devices wherein data from at least one sensor or input is displayed in discrete real time on a human readable digital display in discrete real time. Typically the invention monitors the resistance of at least one electrostatic dissipation device in contact with a person, is capable of detecting and possibly responding to electrostatic events or voltage threats, and utilizes the presence of electrical noise on analog input as an indication that the apparatus is operating as expected.

### FEDERAL RESEARCH STATEMENT

N/A

### SEQUENCE LISTING

N/A

### CROSS REFERENCE TO RELATED APPLICATIONS

N/A

### BACKGROUND OF THE INVENTION

Electrostatic voltages are known to provide a threat to electronic components. Electronic components can be damaged when a charge stored on a person, on a piece of equipment, or on a surface rapidly dissipates or discharges through an electronic component or assembly.

An accumulation of extra electrons occurs naturally when two predominantly insulated surfaces are rubbed together. For example rubbing ones feet across the carpet can easily cause a voltage of thousands of volts to accumulate on a person. In this instance the person is insulated from a ground or from a conductive surface by the carpet, as the person rubs their feet they accumulate extra electrons. Since each electron has a charge typically measured in Coulombs (C) the more electrons accumulated on the person, the higher the charge a person carries. The person is storing charge just like a capacitor stores charge, by accumulating electrons. Such accumulated charge is referred to as a static charge because it is not moving relative to the person or surface on which the charge is accumulated.

If a person is significantly charged and touches a door knob a spark frequently jumps between the person and the door knob. This event discharges some or all of the accumulated charge on the individual and into the door knob through an electrostatic discharge event.

The charge carried by a single electron is e, and e=−1.602×10⁻¹⁹ C (Coulombs). The number of Coulombs (C) stored on a capacitor, typically measured in Farads (F) determines the voltage (V) stored on the capacitor such that 1 C/1 F=1V. By this formula one Coulomb stored on a 1 Farad capacitor has a voltage of 1 volt.

This formula shows that increasing the number of electrons stored on a surface increases the charge stored on the surface while increasing the voltage. The voltage increases proportionally to the capacitance (the number of Farads) of the surface, where the charge is proportional to the number of electrons stored on or in the surface. Voltages stored statically in such a way are commonly referred to as electrostatic voltages.

Individuals can easily store thousands of volts on their body. If discharged rapidly into an electronic component or assembly the electronic component or assembly may be damaged or destroyed. Some components can be damaged with as little as 50 volts of potential across critical junctions. Similarly static charge can accumulate on pieces of equipment or on surfaces when two surfaces are rubbed together.

Such accumulated charges stored on individuals, equipment, or on surfaces presents a threat to the viability of electronic components and assemblies especially when those components are not in a protective case. Manufacturing environments where electronic components are fabricated or assembled into assemblies are prime examples where static can easily damage the electronics if the buildup of excessive charge is not managed.

Various pieces of equipment designed to mitigate threats from electrostatic voltages such equipment includes wrist straps, foot straps, mats, de-ionizers, and electrostatic dissipation device testers.

Wrist straps, foot straps, and mats are examples of electrostatic discharge devices. Such devices have a resistance optimized to conduct electricity slowly. If the resistance is too low, the device will conduct electricity rapidly, if the resistance is too high, the device will not dissipate a static charge efficiently.

Controlling the series resistance of a person in in contact with one or more electrostatic dissipation devices is critical to controlling electrostatic charge accumulation in an electronic manufacturing environment. Typically an operator will wear or be in contact with one or more electrostatic dissipation devices when they are working. Wrist straps and foot straps are typically worn by an individual. Electrostatic dissipative mats are frequently placed on tables in work areas to keep static charge from accumulating on the tables or work areas.

Electrostatic discharge devices prevent charge from accumulating on surfaces or on persons in contact with them by conducting charge to ground. Electrostatic discharge devices also prevent the rapid discharge of accumulated charge when a highly charged object or person contacts them initially by conducting charge to ground slowly.

Measuring the series resistance of a person in contact with an electrostatic discharge device is therefore important to mitigating both charge accumulation and rapid discharge of accumulated charge. In this document the term operator resistance or resistance of the operator is the series resistance of a person in contact with an electrostatic discharge device. Optimally the operator resistance should be between 600 thousand ohms and 3 million ohms.

Electrostatic dissipation device testers typically determine the operator resistance by first applying a known voltage across a known resistance in that is connected in series with the operator resistance. The voltage drop across the operator resistance is then measured and ohms law is used to calculate the resistance of the operator.

Conventional testers capable of testing operator resistance do so by using two analog comparators. The analog comparators compare the voltage drop across the operator resistance to a voltage set by a voltage divider network. Typically one analog comparator is configured to activate when the operator resistance is too low, and the second analog comparator is configured to activate when the operator resistance is too high. Such testers test are limited to reporting pass, fail low (resistance too low) and, fail high (resistance too high).

Limitations of testers sold in this market place also include crude displays. For example when performing tests, some testers flash red and green status LEDs simultaneously, and then illuminate a green LED or a red LED indicating that a test has passed or failed respectively. Such displays can confuse operators or cause operators to have questions about the efficacy of the tester.

Conventional testers are also not intelligent, they cannot detect when someone has short circuited a part of the tester or manipulated the tester to derive a false pass.

Because of these limitations, operators frequently simply attempt to obtain a pass before proceeding to work. Because they do not have a dynamic sense of how effective their electrostatic discharge devices are functioning operators will frequently move around their wrist straps, add conductive lotions, grab their wrist, or even make a direct connection to a known impedance simply to obtain a pass from the tester.

Before the invention described in this disclosure no tester in the electrostatic dissipation device test market had the ability to display the operator resistance on a digital display in discrete real time.

Before the invention described in this disclosure no tester in the electrostatic dissipation device test market had the intelligence to detect when a test of an electro static dissipation device had been tampered with besides the ability to test for too low of an impedance when a wrist strap, or foot strap was short circuited to ground.

### SUMMARY OF THE INVENTION

The invention relates to a process and an apparatus for monitoring electrostatic threats or events, and for testing electrostatic dissipation devices wherein data from at least one sensor or input is displayed in discrete real time on a human readable digital display.

The invention includes at least one microcomputer that contains or is in communication with one or more analog to digital converters. Embodiments of microcomputers include a digital signal processor, a microprocessor, an FPGA configured with microprocessor functions, or other compute engine known in the art.

Typically an input from a sensor or from an electrostatic dissipation device is in communication with an analog to digital converter and the analog to digital converter is in communication with the microcomputer. The analog to digital converter samples an analog input and converts the value of the analog input into a digital value. The microcomputer then configures one or more of these digital values to be displayed on a digital display. The microcomputer may also configure these digital values to be sent over a data communication interface. In yet other instances the microcomputer analyzes one or more of these digital values looking for threats, fault conditions, or failures. The microcomputer may initiate an alarm, display a message, or indicate a failure if a threat if a threat, fault, or failure is detected.

Analog inputs are typically sampled and converted into the digital domain many times per second. When these digitized values are displayed on a digital display continuously, they provide an operator with a real time sense of their operator resistance from moment to moment. Such a sampled system is commonly referred to as a discrete real time system because each sample corresponds to a specific value measured at a specific time that is converted into the digital domain. Preferred embodiments of the invention sample and display a plurality of inputs continuously.

In some embodiments the invention also uses the presence of electrical noise on analog inputs to authenticate proper operation of the apparatus.

The invention also typically includes the ability to communicate with one or more computers or devices through a wired or wireless communication data communication interface. Examples of wired data communication interfaces include yet are not limited to RS232, RS485, Ethernet, wired USB. Examples of wireless data communication interfaces include yet are not limited to standard WIFI, or Bluetooth.

A preferred embodiment of the invention displays in discrete real time the resistance of at least one electrostatic dissipation device in contact with a person (the operator resistance). Other embodiments of the invention include the real time monitoring of a voltage, typically an electrostatic voltage in communication with a reference plane.

Some embodiments of the invention have programmable fault, failure, and/or alarm thresholds. In these embodiments an external computer or device can change one or more of these thresholds by sending commands to the apparatus over the data communication interface.

### DETAILED DESCRIPTION OF THE INVENTION

The invention relates to a process and an apparatus for monitoring electrostatic threats or events, and for testing electrostatic dissipation devices wherein data from at least one sensor or input is displayed in discrete real time on a human readable digital display.

The invention includes at least one microcomputer that contains or is in communication with one or more analog to digital converters. Embodiments of microcomputers include a digital signal processor, a microprocessor, an FPGA configured with microprocessor functions, or other compute engine known in the art.

Typically an input from a sensor or from an electrostatic dissipation device is in communication with an analog to digital converter and the analog to digital converter is in communication with the microcomputer. The analog to digital converter samples an analog input and converts the value of the analog input into a digital value. The microcomputer then configures one or more of these digital values to be displayed on a digital display. The microcomputer may also configure these digital values to be sent over a data communication interface. In yet other instances the microcomputer analyzes one or more of these digital values looking for threats, fault conditions, or failures. The microcomputer may initiate an alarm, display a message, or indicate a failure if a threat if a threat, fault, or failure is detected.

Analog inputs are typically sampled and converted into the digital domain many times per second. When these digitized values are displayed on a digital display continuously, they provide an operator with a real time sense of their operator resistance from moment to moment. Such a sampled system is commonly referred to as a discrete real time system because each sample corresponds to a specific value measured at a specific time that is converted into the digital domain. Preferred embodiments of the invention sample and display a plurality of inputs continuously.

In some embodiments the invention also uses the presence of electrical noise on analog inputs to authenticate proper operation of the apparatus. In these embodiments the absence electrical noise on analog input is an indication that the system is not functioning properly, or has been tampered with. Examples include short circuiting a common ground to earth ground, and placing a known resistance with short lead length between an analog input and a ground. The absence of electrical noise includes the instance where the electrical noise level is below a certain minimum level. Since embodiments of the invention use electrical noise as a measure of system efficacy and since electrical noise may be observed as variance in a reading, a measurement, or a voltage, observing a variance of electrical noise that is below a threshold level for electrical noise is an indication that the system is not functioning properly, or has been tampered with.

The invention also typically includes the ability to communicate with one or more computers or devices through a wired or wireless data communication interface, such embodiments of the invention therefore may include connectors, antenna, or other electronic components configured to communicate with data communication interfaces. Examples of wired data communication interfaces include yet are not limited to RS232, RS485, Ethernet, wired USB. Examples of wireless data communication interfaces include yet are not limited to standard WIFI, or Bluetooth.

A preferred embodiment of the invention displays in discrete real time the resistance of at least one electrostatic dissipation device in contact with a person (the operator resistance). Other embodiments of the invention include the real time monitoring of a voltage, typically an electrostatic voltage in communication with a reference plane.

The invention in one embodiment enables one or more persons to monitor their operator resistance(s) when in contact with one or more electrostatic dissipation devices in discrete real time. Preferred embodiments of the invention allow more than one persons to monitor their individual operator resistances simultaneously.

In other embodiments a sensor or circuit capable of measuring a voltage is used to monitor electrostatic events or voltages when they are in close proximity to the testing apparatus. Such an embodiment may also include an audio or visual alarm or warning. For example if an electrostatic event or a significant electrostatic voltage is detected, the microcomputer could sound an alarm and/or display a warning or alarm message on the digital display. Alarm or warning messages may also be sent through a transmission medium to an external computer and/or to other devices. Alarm or warnings, or failure messages may also be displayed on the digital display if an electrostatic device fails a test, or may be initiated by an external computer or device interpreting data from an apparatus consistent with the invention.

One or more microcomputers receiving a series of digital values from one or more analog to digital converters will typically configure the series of digital values to be sent and displayed on a digital display or to be sent across a data communication interface to devices or computers external to the apparatus of the invention.

A simplified conceptual model of one embodiment of the invention is depicted in FIG. 1. Here an apparatus of the invention, an electrostatic device tester and data logging unit, item 1 has a plurality of inputs S1, S2, SN-1, and SN are shown. Each input is connected with an analog to digital converter: input S1 is connected to analog to digital converter 1 ADC1, input S2 is connected to analog to digital converter 2 ADC2, input SN-1 is connected to analog to digital converter ADCN-1, and input SN is connected to analog to digital converter ADCN. A series of dots shown as Item SE depicts an extensible structure where any number of inputs may be incorporated into the invention. In FIG. 1 the analog to digital converters are contained within microcomputer CPU. Microcomputer CPU is in communication with a display buffer BUF, and data communication interface COM.

FIG. 1 also shows input S1 connected to item 2: input S1 is directly connected to electrostatic discharge device 1 ESD1, ESD1 is connected to a first person OP1, OP1 is also connected to common ground C. Furthermore common ground C connects to electrostatic device tester and data logging unit item 1 forming a closed electrical circuit. Item 2 is the operator resistance of a first operator; it is the resistance of electrostatic discharge device 1 ESD1 and a first person OP1 connected in series.

The resistance of item 2 (EDS1 in series with OP1) may be measured by item 1 using techniques standard in the art, including yet not limited to connecting a known voltage V1 to a known resistance R1, which in turn is connected in series to item 2. The resistance of item 2 may be determined by measuring the voltage on S1 and by calculating the resistance using ohms law. The resistance of item 2 is the combined resistance of operator 1 in series with electrostatic discharge device 1 ESD1.

Similarly analog to digital converter 2 ADC2 is connected to input S2 that is connected to electrostatic discharge device 2 ESD2, which in turn is connected to a second person OP2, and second person OP2 is connected to common ground C. Item 3 includes electrostatic device 2 EDS2 connected in series to a second person OP2. The resistance of item 3, a second operator resistance, may be determined by applying a known voltage V2 to resistor R2, by measuring the voltage at input S2 relative to common ground C and calculating the resistance of item 3 using ohms law.

Again a series of dots SE indicates an extensible structure. Analog to digital converter ADCN-1 is connected to input SN-1 which is connected to voltage sensor VS1. Also shown is analog to digital converter ADCN is connected to input SN which is connected to voltage sensor VS2.

In some embodiments voltage sensors VS1 and VS2 are circuits or sensors capable of detecting electrostatic voltages in close proximity to the electrostatic device tester and data logging unit, item 1. Circuits or voltage sensors VS1 and VS2 may be connected to and/or incorporated within the electrostatic device tester and data logging unit, item 1. One such embodiment is when the electrostatic device tester and data logging unit, item 1 monitors the voltage on a conductive or highly conductive surface typically when that surface is connected to a common ground. A rising voltage on this surface is an indication that an electrostatic voltage has come close to the electrostatic device tester and data logging unit, item 1. The invention is capable of generating alarms or warning messages when such rising voltages are observed.

As mentioned above each analog to digital converter in FIG. 1 are contained within microcomputer CPU. Here microcomputer CPU communicates to display buffer BUF using connection 4, and display buffer BUF communicates with a digital display DISP using connection 5. Microcomputer CPU is thus configured to update the digital display DISP continuously.

Microcomputer CPU is configured to receive and send messages to devices 8 external to item 1 (the electrostatic device tester and data logging unit item 1) through communication port COM. Here microcomputer CPU sends and receives data from the communication port COM using communication bus 6. Communication port COM also sends and receives data from external devices 8 using data communication interface 7. Data communication interface 7 may be implemented in various ways that include yet are not limited to wired or wireless data communication interfaces. FIG. 1 also shows an Earth ground E connected to item 1. Earth ground E typically sourced from an alternating current wall outlet will typically be isolated from common ground C by some impedance.

Item 1, the electrostatic device tester and data logging unit in FIG. 1 is thus capable of monitoring a plurality of inputs by sampling them continuously. Item 1 is also capable of displaying what it monitors in discrete real time on a digital display, and is capable of communicating with external devices or computers.

The invention is not limited to the use of a plurality of analog to digital converters as shown in FIG. 1. Alternate embodiments of the invention may use as few as one analog to digital converter.

Yet other embodiments of the invention may have analog multiplexers that switch a plurality of analog inputs to a particular analog to digital converter. Thus there are pluralities of possible configurations where one or more analog inputs are in communication with one or more analog to digital converters which in turn are in communication with one or more microcomputers.

Microcomputers used in the apparatus of the invention typically prepare data to be displayed on a digital display.

Another simplified conceptual model of one embodiment of the invention is depicted in FIG. 2. Here an apparatus of the invention, an electrostatic device tester and data logging unit, item 1 has a plurality of inputs S1, S2, SN-1, and SN are shown. Each input is connected with an analog to digital converter: input S1 is connected to analog to digital converter 1 ADC1, input S2 is connected to analog to digital converter 2 ADC2, input SN-1 is connected to analog to digital converter ADCN-1, and input SN is connected to analog to analog to digital converter ADCN. A series of dots shown as Item SE depicts an extensible structure where a plurality of additional inputs may be incorporated into the invention. Each of the analog to digital converters in FIG. 2 (ADC1, ADC2, ADCN-1, ADCN) are external to microcomputer CPU and communicate with microcomputer CPU using data bus DB. Microcomputer CPU is in communication with a display buffer BUF, and data communication interface COM.

FIG. 2 also shows input S1 connected to item 2: input S1 is directly connected to electrostatic discharge device 1 ESD1, ESD1 is connected to a first person OP1, and OP1 is connected to common ground C. Furthermore common ground C also connects to electrostatic device tester and data logging unit, item 1 forming a closed electrical circuit. Item 2 is the operator resistance of a first operator; it is the resistance of electrostatic discharge device 1 ESD1 and a first person OP1 connected in series.

The resistance of item 2 (EDS1 in series with OP1) may be measured by item 1 using techniques standard in the art, including yet not limited to connecting a known voltage V1 to a known resistance R1, which in turn is connected in series to item 2. The resistance of item 2 may be determined by measuring the voltage on S1 and by calculating the resistance using ohms law. The resistance of item 2 is the combined resistance of operator 1 in series with electrostatic discharge device 1 ESD1.

Similarly analog to digital converter 2 ADC2 is connected to input S2 that is connected to electrostatic discharge device 2 ESD2, which in turn is connected to a second person OP2, and second person OP2 is connected to common ground C. Item 3 includes electrostatic device 2 EDS2 connected in series to a second person OP2. The resistance of item 3, a second operator resistance, may be determined by applying a known voltage V2 to resistor R2, by measuring the voltage at input S2 relative to common ground and calculating the resistance of item 3 using ohms law.

Again a series of dots SE indicates an extensible structure. Analog to digital converter ADCN-1 is connected to voltage sensor VS1. ADCN is connected to input SN which is connected to voltage sensor VS2.

In some embodiments voltage sensors VS1 or VS2 are circuits or sensors capable of detecting electrostatic voltages in close proximity to the electrostatic device tester and data logging unit, item 1. Circuits or voltage sensors VS1 or VS2 may be connected to and/or incorporated within the electrostatic device tester and data logging unit, item 1. One such embodiment is when the electrostatic device tester and data logging unit, item 1 monitors the voltage on a conductive or highly conductive surface typically when that surface is connected to a common ground. A rising voltage on this surface is an indication that an electrostatic voltage has come close to the electrostatic device tester and data logging unit, item 1. The invention is capable of generating alarms or warning messages when such rising voltages are observed.

As mentioned above each analog to digital converter in FIG. 2 is connected to microcomputer CPU using data bus DB. Here microcomputer CPU communicates to display buffer BUF using connection 4, and display buffer BUF communicates with a digital display DISP using connection 5. Microcomputer CPU is thus configured to update the digital display DISP continuously.

Microcomputer CPU is configured to receive and send messages to devices 8 external to item 1 (the electrostatic device tester and data logging unit) through communication port COM. Here microcomputer CPU sends and receives data from the communication port COM using communication bus 6, and communication port COM sends and receives data from external devices 8 using data communication interface 7. Data communication interface 7 may be implemented in various ways that include yet are not limited to wired or wireless data communication interfaces. FIG. 2 also shows an Earth ground E connected to item 1. Earth ground E typically sourced from an alternating current wall outlet will typically be isolated from common ground C by some impedance.

Item 1, the electrostatic device tester and data logging unit in FIG. 2 is thus capable of monitoring a plurality of inputs by sampling them continuously. Item 1 is also capable of displaying what it monitors in discrete real time on a digital display, and is capable of communicating with external devices or computers.

The invention is not limited to the use of a plurality of analog to digital converters as shown in FIG. 2. Alternate embodiments of the invention may use as few as one analog to digital converter.

Yet other embodiments of the invention may have analog multiplexers that switch a plurality of analog inputs to a particular analog to digital converter. Thus there are pluralities of possible configurations where one or more analog inputs are in communication with one or more analog to digital converters which in turn are in communication with one or more microcomputers.

Microcomputers used in the apparatus of the invention typically prepare data to be displayed on a digital display

FIG. 3 shows an electrostatic device tester and data logging unit 1, an electrostatic discharge device (an ESD mat) MAT, a common ground wire CW, a common ground C, a mat sensor input SM, an Earth ground E, and an impedance Z.
Common ground C is not connected directly to Earth ground E in FIG. 3. Instead common ground C is isolated from Earth ground E by impedance Z. Earth ground E connects to impedance Z which in turn connects to common ground C. Impedance Z typically includes resistive, capacitive, and inductive elements.
FIG. 3 depicts the mat sensor input SM connected to common ground wire CW at a point on the ESD mat (MAT). Mat sensor input SM may be used to monitor small voltages on the electrostatic discharge device MAT by measuring voltages between Earth ground E and common ground C. When this voltage is sampled using an analog to digital converter in communication with a microcomputer the microcomputer will observe variations in the voltage. Typically this voltage varies at a low level its appearance is similar background white noise. The amount this voltage varies up and down corresponds to a variance in the voltage corresponding to the amount of electrical noise observed on an analog input.

Some embodiments of the invention observe the voltage on common ground and expect this voltage to vary above an electrical noise threshold level because of the presence of electrical noise. For example a voltage on common ground that does not have a variance that is above the electrical noise threshold level therefore is an indication that someone may have installed the system incorrectly, that someone tampered with the system, or that the system is broken. This varying or variance in the measurement is caused by electrical noise in the system.

The invention may be configured to sound an alarm if the voltage on common ground does not vary as expected. One way to cause the voltage on common ground not to vary is to short circuit common ground to Earth ground by connecting a wire directly between Earth ground and common ground. Such an embodiment of the invention is intelligent as it can monitor and validate that Earth ground is not shorted directly to common ground. Similarly yet other embodiments of the invention are configured to require other analog inputs to vary because of the presence of electrical noise. For example if the measured operator resistance does not vary above a noise threshold level the system may not be operating correctly, or may have been tampered with.

Such embodiments of the invention rely upon the presence of electrical noise as an indication that the system is functioning properly and has not been tampered with.

Operators sometimes attempt to obtain a pass from the tester by shorting common ground to Earth ground. An apparatus consistent with certain embodiments of the invention can therefore detect when Earth ground is intentionally shorted to ground. These embodiments of the invention can therefore detect when it has been tampered with in this way.

Another way that an electrostatic device tester can be tampered with is by connecting a known resistance with short leads between an input and a ground. Short lead length reduces the amount of electrical noise induced or picked up by the input. Typically electrostatic discharge devices have long leads or large surfaces that pick up electrical noise from the environment. Electrostatic discharge device therefore typically have higher levels of noise than short lead length resistors connected to ground.

Other embodiments of the invention monitor the voltage on the common ground of an electrostatic discharge mat looking for the presence of higher voltages. If this voltage increases significantly it is an indication that a highly electrically charged person, piece of equipment, or some other object has moved close to the test unit or onto the mat. In some embodiments of the invention when such a voltage is detected an audio and or visual alarm in the test unit will indicate the presence of such an electrostatic voltage. Alternatively the presence of an electrostatic voltage in proximity to an electrostatic discharge mat may be observed as a variation in the resistance of the electrostatic discharge mat.

FIG. 4 shows an embodiment of the invention, an electrostatic device tester and data logging unit 10 is depicted including a digital display 11, status indicator for Operator 1 item 15, and a status indicator for Operator 2 item 16.

Items 12, 13, and 14 are items displayed on display 11 in FIG. 4.

Item 12 is a showing the resistance for Operator 1 on a scale as indicated with a triangular pointer and with a numeric value below the pointer. One example of electrical noise affecting the measurement of the resistance for Operator 1 may be observed on the digital display by this triangular pointer on a scale moving left to right; in some instances the numeric value may also be observed changing corresponding to electrical noise. A numeric value identifying the test voltage is also shown. The display indicates the resistance of Operator 1 in series with an electrostatic discharge device. A numeric value identifying the test voltage is also shown. The display indicates the resistance of Operator 1 in series with an electrostatic discharge device. A value of 1.69M (1.69 million ohms) is displayed with a test voltage of 212 mv (212 millivolts).

Item 13 is a showing the resistance for Operator 2 on a scale as indicated with a triangular pointer and with a numeric value below the pointer. One example of electrical noise affecting the measurement of the resistance for Operator 2 may be observed on the digital display by this triangular pointer on a scale moving left to right; in some instances the numeric value may also be observed changing corresponding to electrical noise. A numeric value identifying the test voltage is also shown. The display indicates the resistance of Operator 1 in series with an electrostatic discharge device. A value of 3.5M (3.5 million ohms) is displayed with a test voltage of 400 mv (400 millivolts).

Item 14 is a showing of the status of an electrostatic discharge mat indicating that the mat passes its ground test. This is shown as Matt Pass in FIG. 2.

Status indicator 15 displays the status of Operator 1; status indicator 16 displays the status of Operator 2. Status indicators in some embodiments use color as an indication of test status. For example colors may include green for pass, red for fail, yellow for caution, and blue for idle.

In this embodiment the invention enables two operators to view the resistance of themselves in series with an electrostatic discharge device in real time. Typically the operators will see the resistance vary somewhat. This resistance will vary when they move the wrist strap around, when they add conductive lotion, or may vary as noise does on the common ground. Significant variation in this resistance is an indication that an electrostatic discharge device may be defective: If an operator notices this they may decide to replace a wrist strap.

A significant embodiment of the invention begins to monitor inputs to the electrostatic device tester and data logging unit continuously after an event. In these embodiments a test switch is not required. Events that may be used to initiate continuous monitoring include yet are not limited to one or more of the following: a. connecting the electrostatic device tester and data logging unit to a wired or wireless network or device; b. connecting at least one electrostatic discharge device to the tester; c. a change of state in or detected by the electrostatic device tester and data logging unit.

For example the electrostatic device tester and data logging unit may be configured to initiate continuous monitoring when it is plugged into a wired corporate Ethernet network: As soon as the tester/data logging unit is plugged into the network, communications between the Ethernet network and the tester begin. The electrostatic device tester and data logging unit then sends data across the network continuously using standard data communication protocols. Similarly the electrostatic device tester and data logging unit may begin communicating and sending data when connected to other types of wired or wireless communication networks or when connected to at least one other device or computer.

The electrostatic device tester and data logging unit may be configured to initiate continuous monitoring when at least one operator connects an electrostatic discharge device to the tester/data logging unit. In one such embodiment the electrostatic device tester and data logging unit begins to communicate with a wired or wireless network or to other devices/computers as soon as an operator connects the electrostatic discharge device to the tester/data logging unit.

Alternatively other computers or devices may poll the electrostatic device tester and data logging unit to collect data when desired. In other such embodiments the electrostatic device tester and data logging unit may be configured to continuously display acquired data without communicating that data to another device or computer. In such a mode the operators themselves may interact with the electrostatic device tester and data logging unit in locations where external computers, computer networks, or devices are not present or are not available. The electrostatic device tester and data logging unit may thus be configured to operate in a free standing mode independent of external devices.

Continuous monitoring may thus be initiated after any one of a number of events.

FIG. 5 shows a flow chart consistent with an embodiment of the process of the invention.
“a: Sample or Observe Electrostatic Voltage/GND Input(s)” is the first state depicted in FIG. 5. This state samples inputs from circuits or sensors capable of detecting the presence of electrostatic voltages, or inputs monitoring noise on a common ground.
A second state in FIG. 5 “b: Significant Electrostatic Voltage or GND Fault Present?” makes a decision based on sampled inputs to move to state “c: alarm” or move to state “d: Resistance(s) Value(s) OD, & Varying Within Limits”. This decision may be made by an electrostatic device tester and data logging unit, by an operator observing the digital display, or by software monitoring data from the electrostatic device tester and data logging unit. In some embodiments of the invention a ground fault includes the absence of noise on a common ground.
If a significant electrostatic voltage or a ground fault are detected by the state “b: Significant Electrostatic Voltage or GND Fault Present?” the decision is Yes, and a third state “c: Alarm” is initiated. If no significant electrostatic voltage or ground fault are detected in the second state, then the decision is No, and the flow chart moves to a fourth state “d: Sample or Observe ESD devices(s) Resistance(s)” where inputs connected to other electrostatic discharge devices are sampled and their resistances are monitored.
A fifth state in FIG. 5 “e: Resistance(s) Value(s) OK, & Varying Within Limits?” is where the values of resistances are evaluated and decisions are made. This state checks that the resistances of connected electrostatic discharge devices are within a desired range of values, and checks to see that any variations (variances) in those resistances are within certain limits. This process step may also check for the presence of noise on these inputs. Here again decisions made in this process step may be made by the apparatus (an electrostatic device tester and data logging unit), by an operator observing the digital display, or by software monitoring data from the electrostatic device tester and data logging unit operating on an external device or computer. If these resistances are not within a specified range or are not varying as expected, then the decision is No, and a sixth state “f: Failure or Alarm” is entered. A failure or alarm may be indicated visually or using an audio sound. If these resistances are with an expected range or are varying as expected, then the decision is Yes, and the flow chart in FIG. 5 proceeds back to the first state in the flow chart “a: Sample or Observe Electrostatic Voltage/GND Input(s)”.

Some embodiments of the invention include the ability for a remote computer to program alarm or failure thresholds dynamically. For example a central computer located on a network may change the pass/fail criteria for operator resistance by sending a few commands over a data communication interface. In this way the minimum or maximum operator resistance levels for pass or fail may be updated as desired. Similarly the voltage level indicating an excessive electrostatic voltage in close proximity to the tester may be changed from 1000V to 100V as desired. The amount of allowed AC noise on a voltage input may also be programmable. In these embodiments the pass/fail thresholds or alarm thresholds may be changed by an external computer or device. Such thresholds may include yet are not limited to operator resistance too low, operator resistance too high, too high of an electrostatic voltage detected, too much AC noise detected, and too little AC noise detected.

An apparatus consistent with the invention therefore has the ability to display data relating an analog electrostatic dissipation system on a digital display. The apparatus and system in the varied embodiments sample resistances, electrostatic events, electrostatic voltages, or other analog data many times per second. The data displayed on the digital display a virtual real time measurement of the analog input and/or has to ability to activate an alarm bases on sampled events. Such a sampled system is commonly referred to as a discrete real time system because each sample corresponds to a specific value measured at a specific time that is converted into the digital domain. Sampled data may also be sent to other computers or devices using wired or wireless data communication interfaces. Such apparatus may also be configured to analyze and respond to electrostatic threats detected by the apparatus.
The process consistent with the invention utilizes the apparatus to detect and respond to electrostatic threats. Electrostatic threats include yet are not limited to electrostatic voltages, shorting of a common ground to earth ground, and/or excessive variation of the resistance of an electrostatic discharge device. The process may be implemented by an operator, by the electrostatic device tester and data logging unit, or by software operating on an external computer or device. In each instance electrostatic threats are detected when uncharacteristic behavior relating to one or more continuously sampled analog inputs are observed either by an operator, by the apparatus, or by a device or computer external to the apparatus.

Although the disclosure herein refers to certain illustrated embodiments, it is to be understood that these embodiments have been presented by way of example rather than limitation. Corresponding or related structure and methods specifically contemplated, disclosed and claimed herein as part of this invention, to the extent not mutually inconsistent as will be apparent from the context, this specification, and the knowledge of one skilled in the art, including, modifications thereto, which may be, in whole or in part, (i) operable and/or constructed with, (ii) modified by one skilled in the art to be operable and/or constructed with, and/or (iii) implemented/made/used with or in combination with, any parts of the present invention according to this disclosure, include: (I) any one or more parts of the above disclosed or referenced structure and methods and/or (II) subject matter of any one or more of the following claims and parts thereof, in any permutation and/or combination include the subject matter of any one or more of the following claims, in any permutation. The intent accompanying this disclosure is to have such embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention as limited only by the appended claims.

Terms Usage:

Analog digital converter:
An electronic device, component, or portion thereof capable of sampling the value of an analog input at a discrete moment in time and converting the sampled analog value into a digital value.

Discrete real time:
A plurality of samples taken by an analog to digital converter over time yielding a virtual real time data stream of an analog input converted into the digital domain.

Microcomputer:
Digital signal processor (DSP), a microprocessor, an FPGA configured with microprocessor functions, a central processing unit (CPU), or other compute engine known in the art.

Electrostatics threats include:
Accumulated electrostatic charge: Too high of an operator resistance: Too low of an operator resistance: Too variable of an operator resistance:

Electrostatic dissipation devices include:
Wrist straps, foot straps, and mats capable of dissipating charge over time: de-ionizers:

Electrostatic events include:
The rapid discharge of accumulated charge from one place to another: High levels of electrostatic voltage:

Electrostatic voltage:
A non-moving voltage associated with charge accumulation:

Operator Resistance:
The combined series resistance of a person in contact with an electrostatic dissipation device:

### BRIEF DESCRIPTION OF THE DRAWINGS

FIG. 1 shows a simplified conceptual model of one embodiment of the invention.

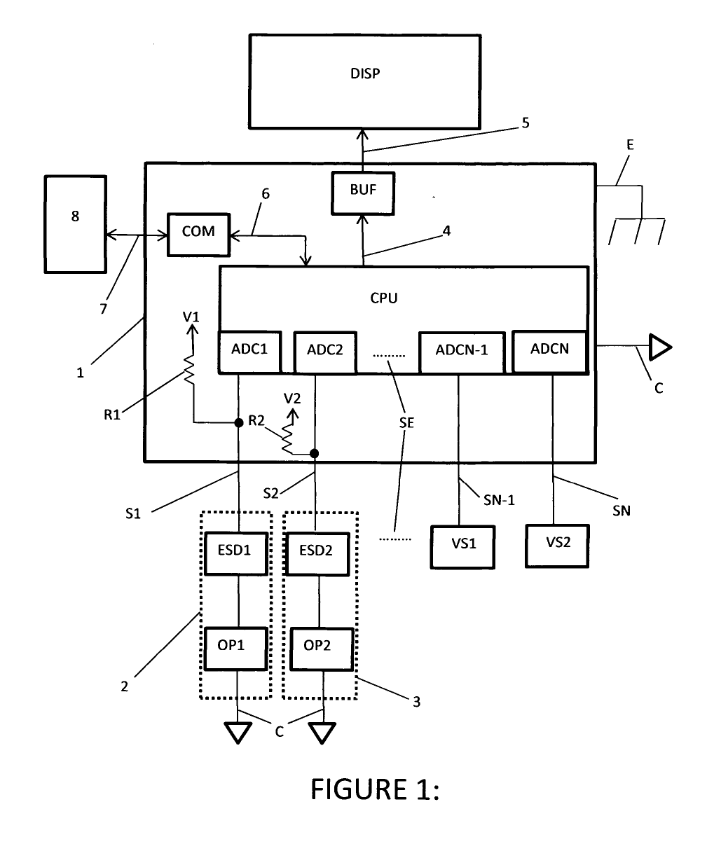

FIG. 2 shows another simplified conceptual model of one embodiment of the invention.

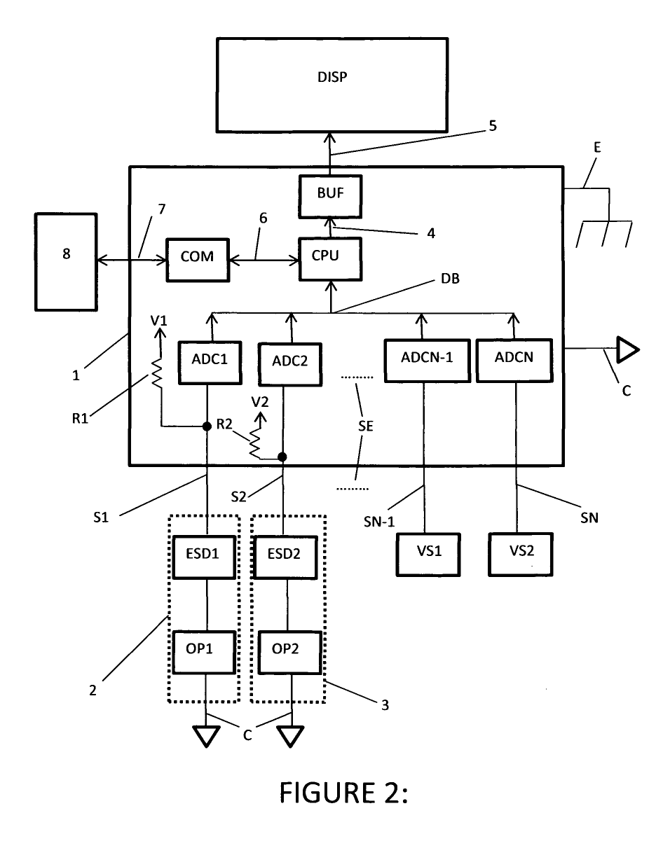

FIG. 3 shows an embodiment of the invention when it is monitoring the efficacy of an electrostatic discharge device (an ESD mat).

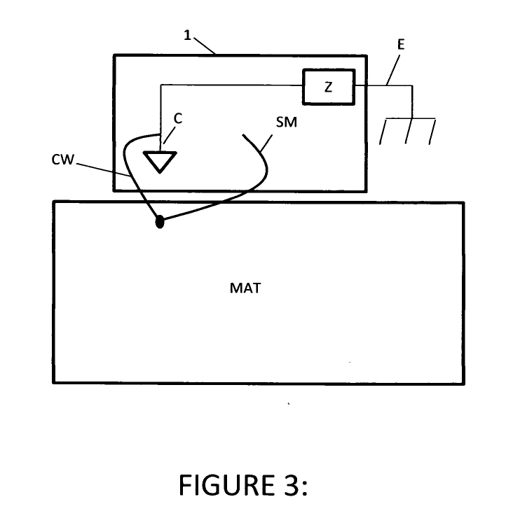

FIG. 4 shows an embodiment of the invention that displays data sampled from a plurality of inputs in discrete real time.

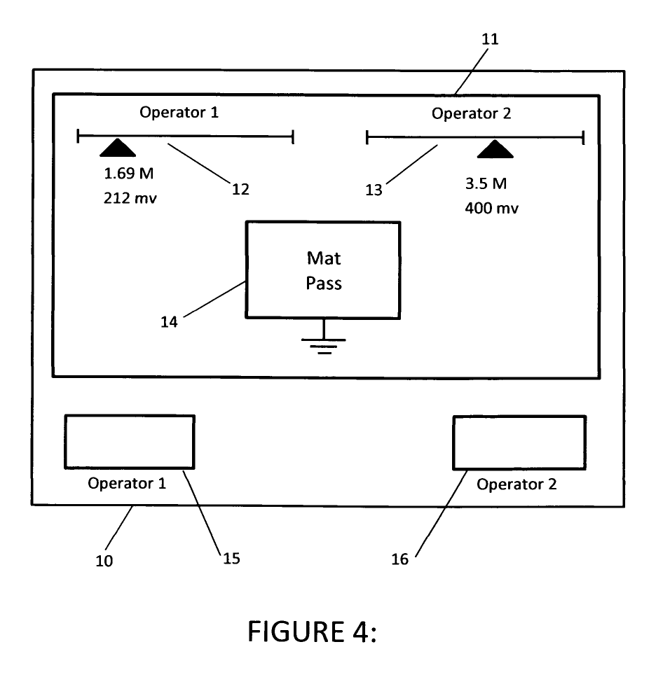

FIG. 5 shows a flow chart consistent with an embodiment of the process of the invention.

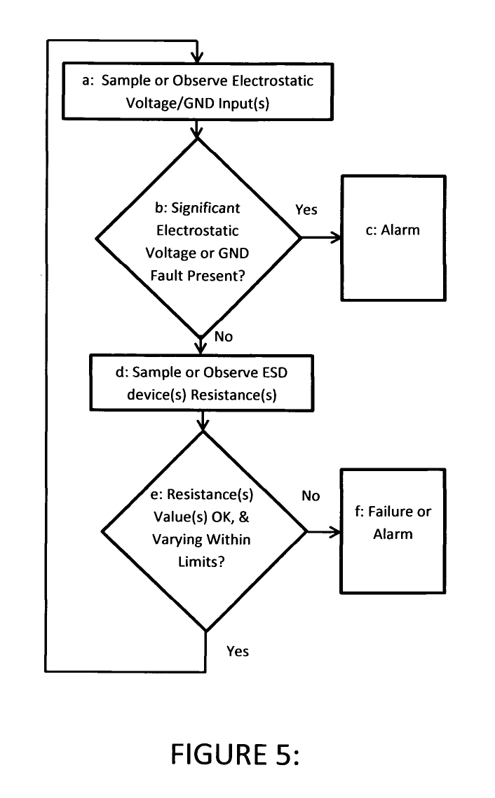

1. An electrostatic device tester and data logging apparatus comprising one or more electrostatic devices, one or more analog inputs, one or more analog to digital converters, one or more microcomputers, one or more digital displays, and one or more data communication interfaces wherein:
a. said one or more electrostatic dissipative devices are connected to said one or more analog inputs, and wherein said one or more analog inputs are in communication with said one or more analog to digital converters;
b. said one or more analog to digital converters sampling said one or more analog inputs continuously converting said one or more analog inputs into one or more series of digital values in discrete real time;
c. said one or more analog to digital converters communicating said one or more series of digital values in discrete real time to said one or more microcomputers; and,
d. said one or more microcomputers controlling said one or more digital displays wherein at least one of said one or more series of digital values in discrete real time is displayed on said one or more digital displays in discrete real time.

2. The electrostatic device tester and data logging apparatus of claim 1 wherein said one or more microcomputers communicates at least one of said one or more series of digital values in discrete real time to at least one external device or computer continuously after an event through said one or more data communication interfaces.

3. The electrostatic device tester and data logging apparatus of claim 1 wherein at least one of said one or more series of digital values displayed in discrete real time on said one or more digital displays has a variance corresponding to electrical noise on said at least one of said one or more analog inputs.

4. The electrostatic device tester and data logging apparatus of claim 3 wherein said one or more microcomputers initiate an alarm, warning, or failure when said variance corresponding to electrical noise on said at least one of said one or more analog inputs is below a first threshold variance value.

5. The electrostatic device tester and data logging apparatus of claim 1 further comprising one or more electrostatic voltage sensing circuits wherein said one or more microcomputers initiate a warning, alarm, or failure when said voltage from said one or more electrostatic voltage detection sensing circuits increases above a threat threshold voltage level.

6. The electrostatic device tester and data logging apparatus of claim 1 further comprising an external computer or device communicating threshold settings to said electrostatic device tester and data logging apparatus over said data communication interface and wherein said electrostatic device tester and data logging apparatus changes said threshold settings corresponding to those thresholds that said external computer or device communicated to said electrostatic device tester and data logging apparatus.

7. The electrostatic device tester and data logging apparatus of claim 1 wherein at least one of said one or more series of digital values displayed in discrete real time on said one or more digital displays corresponds to a measured resistance and electrical noise on at least one of said one or more analog inputs in discrete real time.

8. The electrostatic device tester and data logging apparatus of claim 7 initiating a warning, alarm, or failure upon crossing a threshold level corresponding to said measured resistance value below a minimum resistance threshold or above a maximum resistance threshold and/or upon crossing below a minimum noise threshold.

9. The electrostatic device tester and data logging apparatus of claim 7 wherein at least one of said one or more series of digital values displayed in discrete real time on said one or more digital displays corresponds to a second measured resistance and electrical noise on said one or more analog inputs sampled in discrete real time, and wherein said electrostatic tester and data logging apparatus initiating a warning, alarm, or failure upon crossing a threshold level corresponding to said measured resistance value below a minimum resistance threshold or above a maximum resistance threshold and/or upon crossing below a minimum noise threshold.

10. The electrostatic device tester and data logging apparatus of claim 7 wherein at least one of said one or more series of digital values is displayed on said one or more digital displays as a varying value on a scale.

11. The electrostatic device tester and data logging apparatus of claim 7 wherein at least one said one or more series of digital values is displayed on said one or more digital displays in alpha numeric characters.

12. The electrostatic device tester and data logging apparatus of claim 11 wherein said one or more series of digital values is displayed on said one or more digital displays also includes at least one test measurement voltage.

13. A process for detecting and responding to electrostatic threats comprising:
a. the sampling of one or more analog inputs;
b. converting said one or more analog inputs into one or more series of series of digital values;
c. displaying at least one of said one or more series of digital values on a digital display; and
d. observing said at least one of said one or more series of digital values for a variance below a first threshold level corresponding to electrical noise sampled by an electrostatic device tester and data logging apparatus.

14. The process of claim 13 further comprising observing at least one series of said series of digital values for values and variances corresponding to the operator resistance of a first operator for a value below a minimum resistance threshold or above a maximum resistance threshold for said first operator, and/or for a variance below a minimum noise threshold for said first operator.

15. The process of claim 14 further comprising observing at least one other series of said series of digital values for values and variances corresponding to the operator resistance of a second operator for a value below a minimum resistance threshold or above a maximum resistance threshold for said second operator, and/or for a variance below a minimum noise threshold for said second operator.

16. The process of claim 15 further comprising one or more electrostatic voltage sensors or circuits and observing one or more of said series of digital values for a value of electrostatic voltage exceeding a maximum electrostatic voltage threshold.

17. The process of claim 16 wherein said electrostatic device tester and data logging apparatus initiates a warning, alarm, or failure upon detecting said variance below a first threshold level corresponding to electrical noise sampled by an electrostatic device tester and data logging apparatus, upon detecting an operator resistance below said minimum resistance threshold or above said maximum resistance threshold for said first operator or for said second operator, upon detecting said variance below a minimum noise threshold for said first operator or said second operator, and/or upon detecting said electrostatic voltage exceeding said maximum electrostatic voltage threshold.

18. The process of claim 16 wherein at least one operator performs corrective action upon detecting said variance below a first threshold level corresponding to electrical noise sampled by an electrostatic device tester and data logging apparatus, upon detecting an operator resistance below said minimum resistance threshold or above said maximum resistance threshold for said first operator or for said second operator, upon detecting said variance below a minimum noise threshold for said first operator or said second operator, and/or upon detecting said electrostatic voltage exceeding said maximum electrostatic voltage threshold.

19. The process of claim 16 further comprising sending of at least one of said one or more series of digital values to an external device or computer.

20. The process of claim 19 wherein said external device or computer initiates a warning, alarm, or failure upon detecting said variance below a first threshold level corresponding to electrical noise sampled by an electrostatic device tester and data logging apparatus, upon detecting an operator resistance below said minimum resistance threshold or above said maximum resistance threshold for said first operator or for said second operator, upon detecting said variance below a minimum noise threshold for said first operator or said second operator, and/or upon detecting said electrostatic voltage exceeding said maximum electrostatic voltage threshold.
